(19) United States
(12) Patent Application Publication
(10) Pub. No.: US 2005/0274324 A1
(43) Pub. Date: Dec. 15, 2005

(54) Plasma processing apparatus and mounting unit thereof

(75) Inventors: Syuichi Takahashi, Nirasaki-shi (JP); Yasuharu Sasaki, Nirasaki-shi (JP); Tsutomu Higashiura, Nirasaki-shi (JP); Tomoya Kubota, Beverly, MA (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/094,459

(22) Filed: Mar. 31, 2005

Related U.S. Application Data
(60) Provisional application No. 60/589,829, filed on Jul. 22, 2004.

(30) Foreign Application Priority Data
Jun. 4, 2004 (JP) 2004-167106

(51) Int. Cl. C23C 16/00

(52) U.S. Cl. 118/723 E

(57) ABSTRACT

A parallel plate type plasma processing apparatus including a RF feed rod for applying a high frequency power to a susceptor and a temperature detection unit for detecting the temperature of a substrate on the susceptor is configured to reduce an effect that high frequency current flowing in the RF feed rod has on temperature detection of the temperature detection unit. A surface portion of the susceptor serves as a mounting unit including an electrostatic chuck and a heater. A shaft, which is a protection pipe extracted downward from the processing chamber, is provided under the mounting unit. A chuck electrode of the electrostatic chuck serves as an electrode for applying a high frequency voltage. Provided in the shaft are two RF feed rod for supplying a power to the electrode and an optical fiber, i.e., a temperature detection unit, having a dielectric fluorescent material is disposed in a leading end thereof. Then, the two RF feed rods and bar type conductive leads for the heater are alternately arranged at equal intervals in a circumferential direction on a circle having the optical fiber at the center thereof such that the region having therein the optical fiber is an electromagnetic wave-free region since the electric force lines respectively traveling from the RF feed rods to bar type conductive leads are offset with each other.

### FIELD OF THE INVENTION

The present invention relates to a plasma processing apparatus for converting a processing gas into a plasma by applying a high frequency power between an upper electrode and a mounting table and performing a plasma processing on a substrate mounted on the mounting table, and a mounting unit thereof.

### BACKGROUND OF THE INVENTION

In manufacturing semiconductor devices, a plasma processing apparatus is employed to perform a dry etching, a film forming process or the like and, especially, a parallel plate type plasma processing apparatus, wherein a high frequency voltage is applied between an upper electrode and a lower electrode to generate a plasma, is widely used. FIG. 10 shows a schematic diagram of the apparatus including a processing chamber 9 formed of a vacuum chamber; a mounting table 91; a gas supply unit 92 also serving as a gas supply unit; a susceptor 93; an electrostatic chuck 94, wherein a chuck electrode 94a is embedded in a dielectric material 94b; and a gas exhaust pipe 95. In the plasma processing apparatus, for example, a high frequency power is applied between the mounting table 91 and the upper electrode 92 from the high frequency power supply 96 to convert a processing gas into a plasma, whereby a specified process, e.g., an etching, is performed on a semiconductor wafer W (hereinafter, referred to as a wafer) serving as a substrate on the mounting table 91.

In this case, units for controlling and detecting temperature of the wafer W are necessary in order to maintain the temperature of the wafer W at a specified process temperature. For instance, Reference Patent 1 discloses a single-wafer thermal CVD apparatus, wherein a signal line having a temperature detection terminal unit provided in a surface portion of the mounting table and a power feed rod for supplying power to a heater are installed side by side on a central bottom surface of the mounting table and inserted in a shaft, which is a protection pipe extracted downward from the processing chamber, to pass therethrough.

Further, a power feed rod for applying a high frequency voltage to the mounting table 96 is necessary in the plasma processing apparatus shown in FIG. 10. A shaft similar to one disclosed in Reference Patent 1 is preferably employed such that a bar type conductive lead for a heater, a power feed rod for applying a high frequency voltage and a signal line for sending a temperature detection signal can be drawn out to outside through the shaft, thereby making it easy to assemble and disassemble the apparatus.

However, as a design rule of semiconductor devices is getting stricter, the temperature of the wafer W should be still more strictly controlled. Accordingly, a fluorescent optical fiber thermometer is favorably studied as a candidate for a temperature sensor of the wafer. Such a thermometer, wherein brightness of a light from a fluorescent material provided in a leading end of an optical fiber is detected by the optical fiber, will be described in detail in a preferred embodiment. But, when both the optical fiber and the power feed rod for applying a high frequency voltage are inserted in the shaft and a high frequency current flows in the power feed rod, the bar type conductive lead for a heater practically functions as if it is grounded with respect to the high frequency current. Thus, a high frequency electric field is formed, wherein electric lines of force originate from the power feed rod and end on the conductive rod of a heater.

Meanwhile, a fluorescent material disposed in a leading end of the fluorescent optical fiber thermometer is a dielectric material and will emit dielectric heat (Joule heat) in the high frequency electric field. Moreover, Joule heating level becomes high in a plasma processing apparatus using high frequency, causing a detected temperature value to be increased such that a measured temperature value will be different from an actual temperature of the wafer. Further, when the fluorescent material provided at the leading end of the fluorescent optical fiber thermometer is covered with a protection cap made of a metal, an induction heat is generated by a magnetic field formed around the power feed rod to further increase a temperature measurement error.

[Reference Patent 1] U.S. Pat. No. 6,617,553 B2 (FIGS. 1, 4 and 5, and lines 46-52 in 10th column)

### SUMMARY OF THE INVENTION

It is, therefore, an object of the present invention to provide a plasma processing apparatus and a mounting unit thereof capable of accurately detecting a substrate's temperature by reducing an effect that an electric field or magnetic field generated by supplying a high frequency power to power feed path members has on detection of the substrate's temperature.

In accordance with one aspect of the present invention, there is provided a plasma processing apparatus for converting a processing gas into a plasma by applying a high frequency power between a mounting table and an upper electrode installed to face each other in a processing chamber and performing a plasma processing on a substrate mounted on the mounting table, the plasma processing apparatus including: a protection pipe having one end portion disposed at the mounting table; a temperature detection unit for detecting a substrate's temperature, which is formed of a dielectric material, wherein the temperature detection unit has one end portion disposed at the mounting table and the other end thereof is extracted to outside through the protection pipe; power feed path members, provided in the protection pipe, for supplying a high frequency voltage to the mounting table; a heating unit, disposed at the mounting table, for heating the substrate; and conductive path members, provided in the protection pipe, for supplying a power to the heating unit, wherein the power feed rods and the conductive path members are disposed such that the region having therein the temperature detection unit is an electromagnetic wave-free region where the electromagnetic waves traveling from the power feed rods to the conductive path members are offset with each other.

When there are even numbers of the power feed path members, for example, when there are even numbers of the power feed path members, the power feed path members and the conductive path members are arranged symmetrically with respect to any straight lines perpendicularly intersecting each other at a center of the temperature detection unit. Further, when there are odd numbers of the power feed path members, for example, the power feed rods and the same number of conductive path members as the power feed rods are alternately arranged at equal intervals in a circumferential direction on a circle having the temperature detection unit at the center thereof.

Preferably, the temperature detection unit may include dielectric and conductive materials. For instance, the temperature detection unit may include a dielectric layer disposed at a leading end of an optical fiber. In this case, the dielectric layer may be covered with a conductive protection member. Further, a mounting surface portion of the mounting table may be formed of an electrostatic chuck, having an electrode embedded in a dielectric material, for electrostatically attracting a substrate, and the power feed path members may be configured to apply an electrostatic chuck DC voltage and a high frequency voltage for generating plasma to the electrode.

In accordance with another aspect of the present invention, there is provided a plasma processing apparatus for converting a processing gas into a plasma by applying a high frequency power between a mounting table and an upper electrode installed to face each other in a processing chamber and performing a plasma processing on a substrate mounted on the mounting table, the plasma processing apparatus including: a protection pipe having one end portion disposed at the mounting table; a temperature detection unit for detecting a substrate's temperature, which is formed of a conductive material, wherein the temperature detection unit has one end portion disposed at the mounting table and the other end thereof is extracted to outside through the protection pipe; and power feed path members, provided in the protection pipe, for supplying a high frequency voltage to the mounting table, wherein in the region having therein the temperature detection unit formed of a conductive material, the power feed path members are alternately arranged at equal intervals in a circumferential direction on a circle having the temperature detection unit at the center thereof.

In accordance with still another aspect of the present invention, there is provided a mounting unit used in a parallel plate type plasma processing apparatus for performing a plasma processing on a substrate and having a mounting table main body to which a high frequency voltage is applied, including: a protection pipe having one end portion disposed at the mounting table main body; a temperature detection unit for detecting a substrate's temperature, which is formed of a dielectric material, wherein the temperature detection unit has one end portion disposed at the mounting table main body and the other end thereof is extracted to outside through the protection pipe; power feed path members, provided in the protection pipe, for supplying a high frequency voltage to the mounting table main body; a heating unit, disposed at the mounting table main body, for heating the substrate; and conductive path members, provided in the protection pipe, for supplying a power to the heating unit, wherein the power feed path members and the conductive path members are disposed such that the region having therein temperature detection unit is an electromagnetic wave-free region where the electromagnetic waves traveling from the power feed path members to the conductive path members are offset with each other.

In accordance with the present invention, a temperature detection unit formed of a dielectric material, power feed path members for supplying a high frequency voltage to the mounting table, and conductive path members for supplying a power to the heating unit are provided in a protection pipe having one end portion disposed at the mounting table, wherein the power feed rods and the conductive path members are disposed such that the region having therein the temperature detection unit is an electromagnetic wave-free region where electromagnetic waves traveling from the power feed rods to the conductive path members are offset with each other. Consequently, dielectric heating caused by electromagnetic waves is suppressed in the temperature detection unit formed of a dielectric material, thereby reducing a noise component caused by heating in a detected temperature value. As a result, the temperature of substrate can be precisely measured and a favorable process can be performed on the substrate.

Further, similarly in a case that the temperature detection unit is formed of a conductive material, a magnetic field generated around one power feed path member becomes weakened by a magnetic field generated around the other power feed path member. Accordingly, in this case, magnetic force lines generated in the region having therein temperature detection unit become weaker than those generated when only one power feed path member is provided. As a result, generation of induction heating is suppressed in the temperature detection unit, thereby reducing a noise component caused by heating in a detected temperature value.

### DETAILED DESCRIPTION OF THE PREFERRED EMBODIMENTS

There will be described a plasma processing apparatus used for an etching apparatus in accordance with preferred embodiments of the present invention. FIG. 1 illustrates an entire configuration of such a plasma processing apparatus. Reference numeral 2 of FIG. 1 indicates a processing chamber which is sealed and formed of a conductive member such as aluminum. In an upper portion of the processing chamber 2, an upper electrode 3 also serving as a gas shower head, i.e., a gas supply unit for introducing a specified processing gas into the processing chamber 2, is provided such that it is electrically isolated via an insulation member 31. The upper electrode (gas shower head) 3 is grounded and has a plurality of gas supply holes on the bottom surface thereof, so that a processing gas introduced from a processing gas supply unit 33 through a gas supply line 34 can be supplied uniformly on the entire surface of a substrate, e.g., wafer W, which is disposed under the upper electrode 3. To elaborate, the upper electrode 3 is electrically connected to a wall of the processing chamber 2 via a conductive path (not shown) and grounded via a matching box to be described later, whereby plasma is surrounded with a high frequency current path.

A susceptor 4 for mounting the wafer W thereon is disposed in a lower portion of the processing chamber 2, and a vacuum exhaust unit, i.e., a vacuum pump 22, is connected to the bottom surface of the processing chamber 2 via a gas exhaust pipe 21. Further, as shown in FIG. 1, an insulation member 40 may be provided between the susceptor 4 and the processing chamber 2. Besides, a baffle plate 23 having a plurality of holes is installed between the susceptor 4 and an inner peripheral surface of the processing chamber 2 to uniformly discharge the gas. Moreover, a gate valve 25 for opening or closing a transfer port 24 of the wafer W is installed at the sidewall of the processing chamber 2.

The susceptor 4 includes a cylindrical support portion 41 formed of a conductive member such as aluminum. Installed on the top surface of the support portion 41 is a flat circular mounting unit 42 for mounting the wafer W thereon. Further, an elevating pin (not shown) for loading the wafer W from a transfer arm (not shown) is provided inside the susceptor 4.

The mounting unit 42 includes therein a foil-shaped electrode 44 at a top surface side of a dielectric plate 43 formed of a ceramic (e.g., aluminum nitride (AlN)) plate, and a heater 45 (having, e.g., a mesh shape) serving as a heating unit under the electrode 44. The electrode 44 functions as an electrostatic chuck electrode as well as an electrode for applying a high frequency voltage. Thus, the electrode 44 and an upper dielectric portion of the mounting unit 42 serve as an electrostatic chuck for electrostatically attracting the wafer W. Further, a focus ring 20 is disposed to surround the wafer W which is attracted and held on the surface of the dielectric plate 43.

Connected to the central bottom surface of the mounting unit 42 is an upper end of a shaft 5 which is a protection pipe formed of a dielectric material, e.g., ceramic such as aluminum nitride (AlN). An opening 26 is formed in the central bottom portion of the processing chamber 2, and a cylindrical part 51 is formed through the opening 26 to be extended from the lower portion of the susceptor 4. Further, the shaft 5 is inserted to be fitted onto the cylindrical part 51 via the opening 26 while passing through the support portion 41 to be extended upward to a lower end portion of the cylindrical part 51.

Installed inside the shaft 5 are plural (two in this embodiment) RF (radio-frequency) feed rods 6A and 6B (power feed path members) for supplying a high frequency voltage and an electrostatic chuck DC voltage to the electrode 44. Respective upper ends of the RF feed rods 6A and 6B are inserted into the dielectric plate 43 to be electrically connected to the electrode 44, and respective lower ends thereof are protruded downward from the lower end portion of the shaft 5. Reference numeral 52 is a spacer made of an insulating material.

FIG. 2 shows a structure including the mounting unit 42 and the shaft 5, and FIG. 3 shows a cross section of the shaft 5. Even though not shown in FIG. 1, bar type conductive leads (conductive members) 46 and 47 for supplying power to the heater 45 in addition to the RF feed rods 6A and 6B are inserted in the shaft 5 as shown in FIG. 2 and 3. For convenience, a term “bar type conductive lead” is used to be distinguished from the RF feed rods 6A and 6B for supplying a high frequency voltage. Respective upper ends of the bar type conductive leads 46 and 47 are inserted into the dielectric plate 43 to be electrically connected to the heater 45, and respective lower ends thereof are protruded downward from the lower end portion of the shaft 5.

Further, an optical fiber 7 is inserted in the shaft 5. An upper end of the optical fiber 7 is configured to vertically pass through the dielectric plate 43 via a through hole to directly absorb radiant heat from the wafer W mounted on the top surface, i.e., mounting surface, of the dielectric plate 43. A lower end of the optical fiber 7 is protruded downward from the lower end portion of the shaft 5 to be drawn out to outside. As shown in FIG. 4, the optical fiber 7 has a foil-shaped fluorescent material 70 made of a dielectric material, which is attached to a leading end thereof, wherein a temperature detection/control unit 71 sends a flash light through the optical fiber 7 to the fluorescent material 70 and, then, fluorescent light coming from the fluorescent material 70, i.e., a light signal, is transmitted to the temperature detection/control unit 71 therethrough. Further, the fluorescent material 70 is covered with a conductive protection cap 70a made of metal such as aluminum.

The leading end portion of the protection cap 70a is approximately level with the heater 45. Further, the foil-shaped electrostatic chuck electrode 44 is placed very near the surface of the susceptor 4, and the leading end of the protection cap 70a disposed at the leading end portion of the optical fiber 7 is also placed near the surface of the susceptor 4, although shown differently in FIG. 1 due to difficulty in drawing.

In this embodiment, the fluorescent material 70, the protection cap 70a and the optical fiber 7 functionally correspond to a temperature detection unit and form a fluorescent optical fiber thermometer together with the temperature detection/control unit 71. The thermometer works on a measurement principle that when a flash light is illuminated on the fluorescent material, the attenuation pattern of fluorescent lightness almost completely corresponds to the temperature of fluorescent material. Thus, the temperature of the wafer W can be detected by analyzing the attenuation pattern.

There will be described arrangement layout of parts in the shaft 5 with reference to FIG. 3. The optical fiber 7 (depicted as the protection cap 70a in FIG. 3) is disposed on the central axis of the shaft 5. Further, the RF feed rods 6A and 6B for supplying high frequency power and the bar type conductive leads 46 and 47 for the heater are arranged at equal intervals (namely, each central angle is 90 degrees) on a circle having the optical fiber 7 at the center thereof in a circumferential direction. Moreover, two RF feed rods 6A and 6B are disposed to diametrically oppositely face each other, and the bar type conductive leads 46 and 47 for the heater are also arranged likewise to face each other.

Under the shaft 5, a first power feed path unit 61 including power feed paths, which are electrically connected to the RF feed rods 6A and 6B and bar type conductive leads 46 and 47 and bent in an “L” character shape, is coupled to the outer cylindrical part 51. As shown in FIGS. 1 and 5, one end of a second power feed path unit 62, which is horizontally extended, is connected to the side of the first power feed path unit 61. The power feed path units 61 and 62 are configured to be coupled such that corresponding power feed paths are electrically connected to each other.

Disposed at the other end of the second power feed path unit 62 are a cylindrical connector 63 and a flange portion 64, which is formed at a base side of the cylindrical connector 63. The connector 63 is inserted into an opening 81 on the matching box 8 to be connected to a connector 82 (see FIG. 1) in the matching box 8. Further, the flange portion 64 is fixed at the border of the opening 81 on the surface of the matching box 8 by using screws, whereby the second power feed path unit 62 is attached to the matching box 8. Reference numerals 65 and 83 of FIG. 5 are screw holes.

In order to attach the second power feed path unit 62 to the matching box 8, when the connectors 63 and 82 are connected to each other, the flange portion 64 should be disposed on the matching box 8 such that screw holes 65 coincide to be matched with the screw holes 83. Here, the second power feed path unit 62 includes a conductive cylindrical member 66 and power feed paths, which are formed in the cylindrical member 66 while electrically isolated therefrom. But, it is difficult to install the first power feed path unit 61 and matching box 8 at respective sides of the second power feed path unit 62 to be perfectly aligned with each other. Further, as for the second power feed path unit 62, it is hard to properly position the power feed paths in the cylindrical part 66. Thus, in general, for the case of using the cylindrical part 66, it becomes difficult to attach or detach the second power feed unit 62 to or from the matching box 8.

Therefore, one portion of the cylindrical part 66, e.g., the cylindrical part 66's leading end portion connected to the flange portion 64, is formed of a bellows member 67 in this embodiment. Accordingly, the bellows member 67 can accommodate the misalignment in the above position relationship, thereby relieving load stress applied to the cylindrical part 66 and the power feed paths when attaching or detaching the second power feed path unit 62, so that attachment or detachment thereof becomes easy.

FIG. 6 shows a circuit of power feed paths, wherein the power feed paths connected to the RF feed rods 6A and 6B are combined in the matching box 8 and connected to a high frequency power supply unit 84 via a matching circuit 83. Reference numeral 85 is a chuck power supply unit for feeding an electrostatic chuck DC voltage to the electrode 44, which is connected to the power feed paths at output side of the matching circuit 83 via a filter 86. Reference numeral 87 is a heater power supply unit for feeding power to the heater 45, which is connected to the bar type conductive leads 46 and 47 via a filter 88.

Hereinafter, the functions of the plasma processing apparatus (etching processing apparatus) fully described above are explained. First, the gate valve 25 is opened and the wafer W having a mask pattern formed of a resist film on its surface is loaded into the processing chamber 2 by a transfer arm (not shown) from a load-lock chamber (not shown). Then, the wafer w is mounted on the susceptor 4 via the elevating pin (not shown) and a DC voltage is applied to the electrode 44 from the chuck power supply unit 85 via a switch (not shown) and the RF feed rods 6A and 6B, whereby the wafer W is electrostatically attracted and held on the surface of the susceptor 4.

Thereafter, the gate valve 25 is closed to seal the processing chamber 2. The processing chamber 2 is vacuum exhausted via the vacuum pump 22. Further, processing gas, i.e., etching gas, e.g., halogen-based corrosion gas such as HBr, Cl₂ and HCl; oxygen gas; and nonreactive gas (Ne, Ar, Kr, Xe etc.), is introduced at a specified flow rate into the processing chamber 2 through the gas supply line 34. The processing gas is discharged uniformly on the surface of the wafer W through the gas supply holes 32, thereby maintaining a specified vacuum level in the processing chamber 2. Further, a high frequency voltage is applied from the high frequency power supply unit 84 to the electrode 44 via the matching circuit 83 and the RF feed rods 6A and 6B, and a high frequency power is applied between the susceptor 4 and the upper electrode 3. Accordingly, the processing gas, i.e., the etching gas, is converted into plasma, whereby the surface of wafer W is etched by plasma.

Meanwhile, AC or DC voltage of a common frequency is applied to the heater 45 in the susceptor 4 from the heater power supply unit 87 via the bar type conductive leads 46 and 47, whereby the heater 45 emits heat. Further, flash light is illuminated on the fluorescent material 70 (see FIG. 4), which is disposed at the leading end portion of the optical fiber 7, at specified intervals via the optical fiber 7. The fluorescent light from the fluorescent material 70 is attenuated in accordance with an attenuation curve corresponding to the temperature thereof, and the temperature detection/control unit 71 detects the temperature of wafer W based on the attenuation curve. The wafer W is heated by heat from the plasma and heater 45. Thus, based on the wafer's temperature (detected temperature value), the output of heater 45 is controlled by a controller (not shown). As a result, the wafer W is controlled to be kept at a specified process temperature.

Additionally, when high frequency current flows in the RF feed rods 6A and 6B, the bar type conductive leads 46 and 47 to be used for applying a DC voltage practically function as if they are grounded with respect to the high frequency current, thereby forming an electric field where electromagnetic waves travel from the RF feed rods 6A and 6B to the bar type conductive leads 46 and 47, respectively. Here, the RF feed rods 6A and 6B and the bar type conductive leads 46 and 47 are alternately arranged at equal intervals (divided into four parts) in a circumferential direction on a circle having the optical fiber 7 at the center thereof. Accordingly, as shown in FIG. 7, vectors of electric force lines originating from the RF feed rods 6A and 6B become zero in theory. Namely, the region having therein the optical fiber 7, specifically, the fluorescent material 70 that is a dielectric material disposed at the leading end of the optical fiber 7, is an electromagnetic wave-free region since the electromagnetic waves respectively traveling from the RF feed rods 6A and 6B to the bar type conductive leads 46 and 47 are offset with each other. Consequently, the dielectric heating is suppressed in the fluorescent material 70 and the fluorescent material 70 is heated to the temperature corresponding to the wafer's temperature. As a result, the temperature of the wafer W can be precisely measured and a favorable process can be performed.

Further, a magnetic field is generated around the RF feed rods 6A and 6B due to the high frequency current flowing therein, and an eddy current is generated in the protection cap 70a made of a conductive material such as aluminum. However, the protection cap 70a is placed at the midpoint of a line that links the two RF feed rods 6A and 6B, and magnetic force lines MA and MB whose magnitudes are same in theory are generated, e.g., clockwise around the respective RF feed rods 6A and 6B as shown in FIG. 7. Accordingly, the effects of magnetic force lines MA and MB are offset with each other at an arbitrary point of time at the region of the protection cap 70a. As a result, generation of an eddy current is suppressed at the protection cap 70a and an induction heating level is low, whereby the temperature can be further precisely detected.

The susceptor 4 in the above-described embodiment corresponds to a mounting table main body of another embodiment of the invention. Further, the shaft 5, the RF feed rods 6A and 6B, the bar type conductive leads 46 and 47, and the temperature detection unit in the above-described embodiment correspond to a mounting unit of another embodiment of the invention.

Further, in order to obtain the effect of the present invention, the number of the RF feed rods to be used for applying a high frequency power is not limited to two, and can be equal to or more than three. When there are even numbers of the power feed path members, the RF feed rods 6A and 6B and the bar type conductive leads 46 and 47 are disposed on the same circle in a circumferential direction in the above description, but a circle including the RF feed rods 6A and 6B at its periphery may be different in size from a circle including the bar type conductive leads 46 and 47 at its periphery. In other words, the power feed path members and the conductive path members may be arranged symmetrically with respect to any straight lines perpendicularly intersecting each other at a center of the temperature detection unit. For instance, FIG. 9 shows another arrangements of the power feed path members and the conductive path members. In this case, the fluorescent material 70 (optical fiber 7), the power feed path members 6A and 6B, and the conductive path members 46 and 47 are disposed in a straight line. The same effect can be obtained as well.

FIG. 9 depicts an arrangement layout of three power feed path members 6A to 6C and three conductive path members 46 to 48, and electric and magnetic fields. The power feed path members and conductive path members are alternately arranged at equal intervals with opening angles of 60 degrees. Also in this case, as shown in FIG. 9A, the region having therein the fluorescent material 70 is an electromagnetic wave-free region since the electromagnetic waves respectively traveling from the RF feed rods 6A, 6B and 6C to the bar type conductive leads 46, 47 and 48 are offset with each other. Further, as shown in FIG. 9B, magnetic force lines MA to MC around the RF feed rods 6A to 6C are offset at an arbitrary point of time at the region of the protection cap 70a. Namely, composition vectors of magnetic force lines become zero in theory in a region where the fluorescent material 70 is disposed. When a plurality of power feed path members are provided as described above, the RF feed rods and the same number of conductive path members as the RF feed rods may be alternately arranged at equal intervals in a circumferential direction on a circle having the temperature detection unit at the center thereof.

Further, the above-mentioned arrangement layout can be applied to a case where a temperature detection unit is formed of a conductive material. But, in the case, bar type conductive leads for supplying power to a heater can be arranged without any restriction.

A plasma processing apparatus of the present invention can be a CVD apparatus without being limited to an etching apparatus.

### BRIEF DESCRIPTION OF THE DRAWINGS

FIG. 1 schematically illustrates a vertical section showing an entire configuration of a plasma processing apparatus in accordance with a preferred embodiment of the present invention;

FIG. 2 depicts a perspective view schematically showing a shaft that is a protection pipe provided in a lower portion of a mounting table and an enlarged diagram of one portion of the shaft;

FIG. 3 is a cross section of the shaft;

FIG. 4 depicts an explanatory diagram showing an exemplary thermometer including a temperature detection unit in accordance with the preferred embodiment of the present invention;

FIG. 5 is an explanatory diagram showing a method for attaching RF feed rods to a matching box in accordance with the preferred embodiment of the present invention;

FIG. 6 is a circuit diagram showing a circuit configuration including the matching box in accordance with the preferred embodiment of the present invention;

FIG. 7 is an explanatory diagram showing electric and magnetic fields generated by a high frequency current flowing in a power supply path member in accordance with the preferred embodiment of the present invention;

FIG. 8 is an explanatory diagram showing electric and magnetic fields generated by a high frequency current flowing in a power supply path member in accordance with another preferred embodiment of the present invention;

FIG. 9 illustrates an explanatory diagram showing electric and magnetic fields generated by a high frequency current flowing in a power supply path member in accordance with still another preferred embodiment of the present invention; and

FIG. 10 shows a vertical section of a conventional plasma processing apparatus.

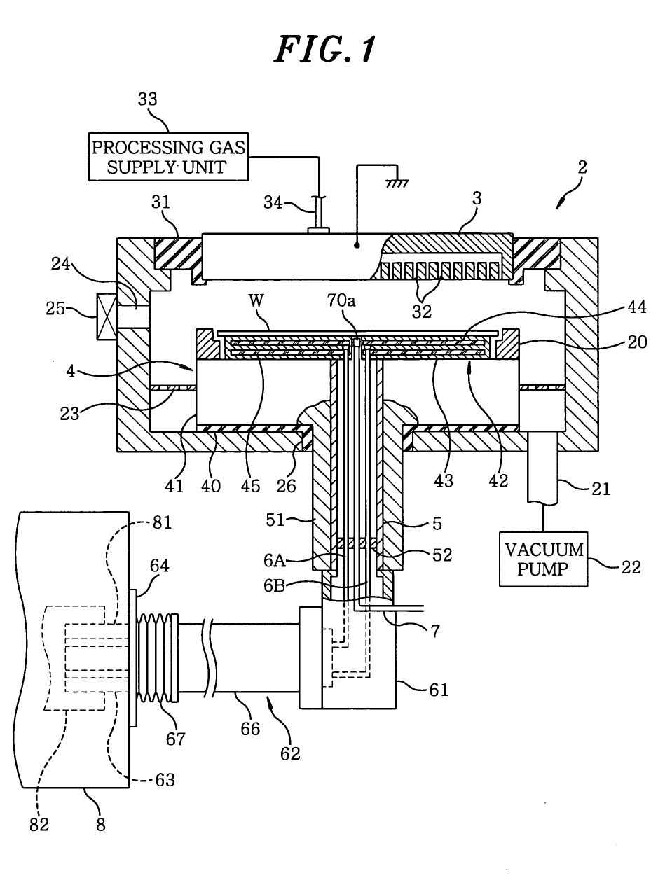

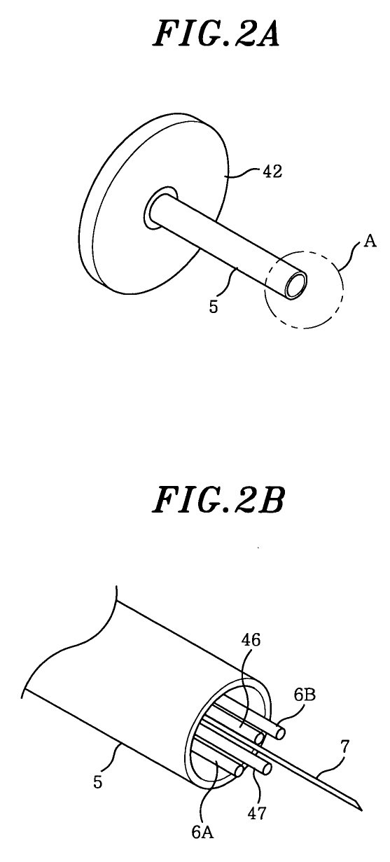

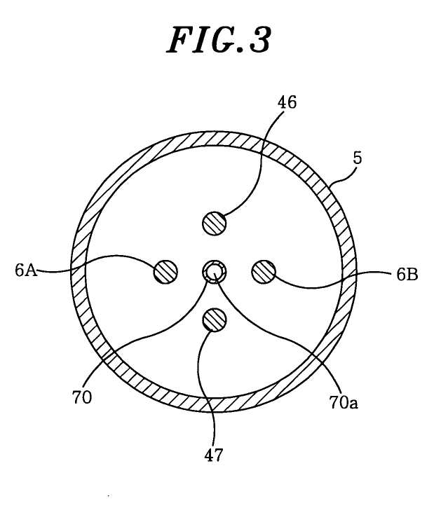

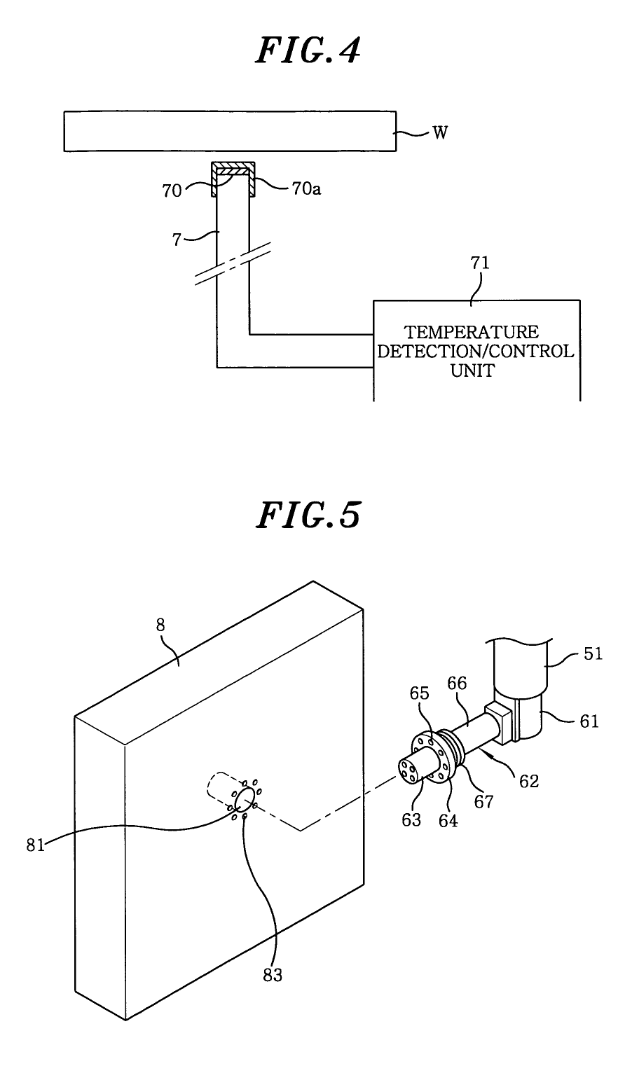

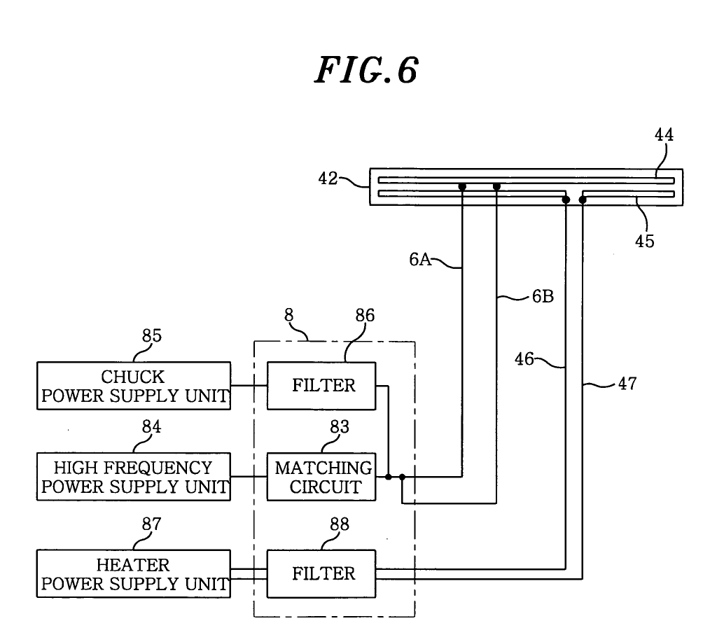

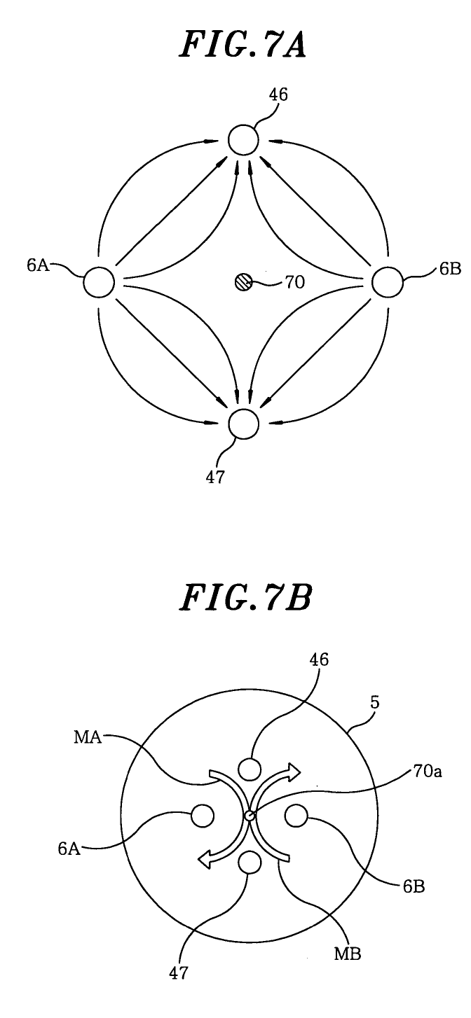

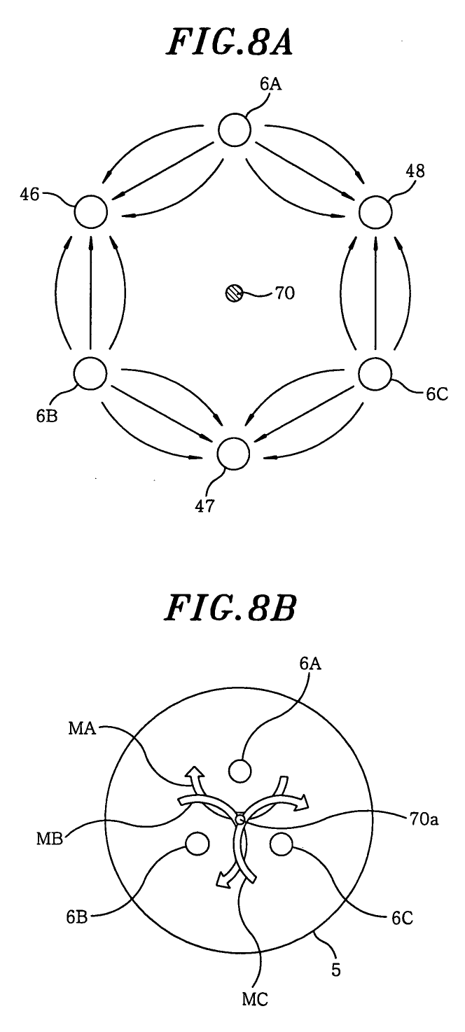

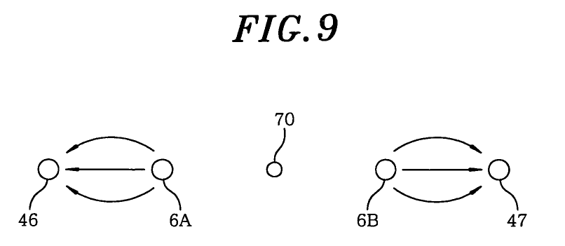

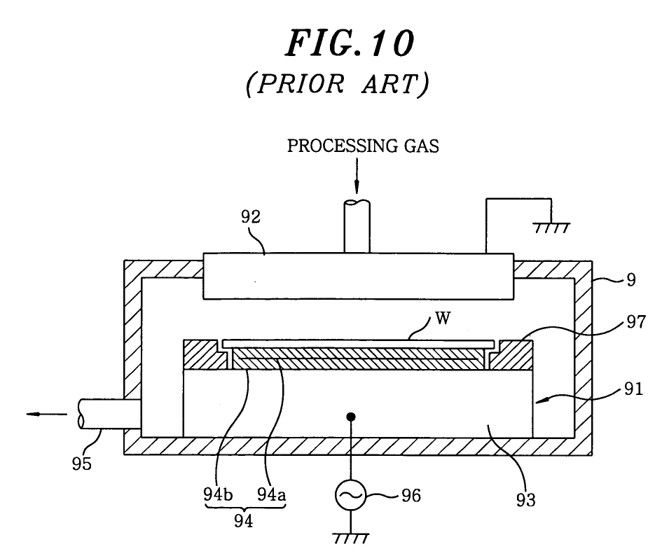

### DESCRIPTION OF THE REFERENCE NUMERALS

W: wafer

2: processing chamber

3: upper electrode

4: susceptor

41: support portion

42: mounting unit

43: dielectric plate

44: electrode

45: heater

46, 47: bar type conductive lead for a heater

5: shaft

6A, 6B, 6C: RF feed rod for supplying a high frequency power

61: first power feed path unit

62: second power feed path unit

67: bellows

7: optical fiber

70: fluorescent material

70a

8: matching box

1. A plasma processing apparatus for converting a processing gas into a plasma by applying a high frequency power between a mounting table and an upper electrode installed to face each other in a processing chamber and performing a plasma processing on a substrate mounted on the mounting table, the plasma processing apparatus comprising:
a protection pipe having one end portion disposed at the mounting table;
a temperature detection unit for detecting substrate's temperature, which is formed of a dielectric material, wherein the temperature detection unit has one end portion disposed at the mounting table and the other end is extracted to outside through the protection pipe;
power feed path members, provided in the protection pipe, for supplying a high frequency voltage to the mounting table;
a heating unit, disposed at the mounting table, for heating the substrate; and
conductive path members, provided in the protection pipe, for supplying a power to the heating unit,
wherein the power feed path members and the conductive path members are disposed such that the region having therein the temperature detection unit is an electromagnetic wave-free region where electromagnetic waves traveling from the power feed path members to the conductive path members are offset with each other.

2. The plasma processing apparatus of claim 1, wherein when there are even numbers of the power feed path members, the power feed path members and the conductive path members are arranged symmetrically with respect to any straight lines perpendicularly intersecting each other at a center of the temperature detection unit.

3. The plasma processing apparatus of claim 1, wherein when there are odd numbers of the power feed path members, the power feed path members and the same number of conductive path members as the power feed path members are alternately arranged at equal intervals in a circumferential direction on a circle having the temperature detection unit at the center thereof.

4. The plasma processing apparatus of any one of claims 1 to 3, wherein the temperature detection unit includes dielectric and conductive materials.

5. The plasma processing apparatus of any one of claims 1 to 4, wherein the temperature detection unit includes a dielectric layer disposed at a leading end of an optical fiber.

6. The plasma processing apparatus of claim 5, wherein the dielectric layer is covered with a conductive protection member.

7. The plasma processing apparatus of any one of claims 1 to 6, wherein a mounting surface portion of the mounting table is formed of an electrostatic chuck, having an electrode embedded in a dielectric material, for electrostatically attracting a substrate; and
the power feed path members are configured to apply an electrostatic chuck DC voltage and a high frequency voltage for generating plasma to the electrode.

8. A plasma processing apparatus for converting a processing gas into a plasma by applying a high frequency power between a mounting table and an upper electrode installed to face each other in a processing chamber and performing a plasma processing on a substrate mounted on the mounting table, the plasma processing apparatus comprising:
a protection pipe having one end portion disposed at the mounting table;
a temperature detection unit for detecting substrate's temperature, which is formed of a conductive material, wherein the temperature detection unit has one end portion disposed at the mounting table and the other end thereof is extracted to outside through the pipe; and
power feed path members, provided in the protection pipe, for supplying a high frequency voltage to the mounting table,
wherein in the region having therein the temperature detection unit formed of a conductive material, the power feed path members are alternately arranged at equal intervals in a circumferential direction on a circle having the temperature detection unit at the center thereof.

9. A mounting unit used in a parallel plate type plasma processing apparatus for performing a plasma processing on a substrate and having a mounting table main body to which a high frequency voltage is applied, comprising:
a protection pipe having one end portion disposed at the mounting table main body;
a temperature detection unit for detecting substrate's temperature, which is formed of a dielectric material, wherein the temperature detection unit has one end portion disposed at the mounting table main body and the other end thereof is extracted to outside through the protection pipe;
power feed path members, provided in the protection pipe, for supplying a high frequency voltage to the mounting table main body;
a heating unit, disposed at the mounting table main body, for heating the substrate; and
conductive path members, provided in the protection pipe, for supplying a power to the heating unit,
wherein the power feed path members and the conductive path members are disposed such that the region having therein temperature detection unit is an electromagnetic wave-free region where electromagnetic waves traveling from the power feed path members to the conductive path members are offset with each other.

10. The mounting unit of the plasma processing apparatus of claim 9, wherein when there are even numbers of the power feed path members, the power feed path members and the conductive path members are arranged symmetrically with respect to any straight lines perpendicularly intersecting each other at a center of the temperature detection unit.

11. The mounting unit of the plasma processing apparatus of claim 9, wherein when there are odd numbers of the power feed path members, the power feed path members and the same number of conductive path members as the power feed path members are alternately arranged at equal intervals in a circumferential direction on a circle having the temperature detection unit at the center thereof.

12. The mounting unit of the plasma processing apparatus of any one of claims 9 to 11, wherein the temperature detection unit includes dielectric and conductive materials.

13. The mounting unit of the plasma processing apparatus of any one of claims 9 to 12, wherein a mounting surface portion of the mounting table main body is formed of an electrostatic chuck, having an electrode embedded in a dielectric material, for electrostatically attracting a substrate; and
the power feed path members are configured to apply an electrostatic chuck DC voltage and a high frequency voltage for generating plasma to the electrode.
